(19) United States
(12) Patent Application Publication
(10) Pub. No.: US 2020/0286775 A1
(43) Pub. Date: Sep. 10, 2020

(54) INTERCONNECT STRUCTURE AND METHOD FOR PREPARING THE SAME

(71) Applicant: NANYA TECHNOLOGY CORPORATION, NEW TAIPE CITY (TW)

(72) Inventors: MAO-YING WANG, NEW TAIPEI CITY (TW); SHING-YIH SHIH, NEW TAIPEI CITY (TW); HUNG-MO WU, NEW TAIPEI CITY (TW); YUNG-TE TING, TAOYUAN CITY (TW); YU-TING LIN, NEW TAIPEI CITY (TW)

(21) Appl. No.: 16/291,376

(22) Filed: Mar. 4, 2019

(51) Int. Cl. H01L 21/768; H01L 23/522; H01L 23/528

(52) U.S. Cl. CPC H01L 21/76816; H01L 23/5226; H01L 23/5283; H01L 21/76877; H01L 21/76843; H01L 21/7684; H01L 21/76805

(57) ABSTRACT

The present disclosure provides an interconnect structure. The interconnect structure includes a first connecting line, a second connecting line disposed over the first connecting line, and a connecting via disposed in a dielectric structure between the first connecting line and the second connecting line, and electrically connecting the first connecting line and the second connecting line. The connecting via includes a head portion and a body portion, and a width of the head portion is greater than a width of the body portion.

### TECHNICAL FIELD

The present disclosure relates to an interconnect structure and a method for preparing the same, and more particularly, to an interconnect structure including a connecting via and a method for preparing the same.

### DISCUSSION OF THE BACKGROUND

In order to build modern integrated circuits, it is necessary to fabricate millions of active devices such as transistors on a single substrate. These individual devices are electrically connected by means of metal wiring to form circuits. Further, vias are used to electrically connect lower and upper metal wirings. Since active devices invariably require more than one level of interconnect, a multi-level interconnect structure is a key element for ultra large scale integration (ULSI) technology. Moreover, the reliability of the integrated circuits is related to the quality of via plugs.

In a multi-level interconnect structure, it is necessary to pass current from one level of metal wiring to another through via plugs. When the metal design rules are scaled down, the size of the via hole is also reduced, thus increasing an aspect ratio of a via hole in which the via is to be formed.

When the aspect ratio of the via hole is increased, it is difficult to fill the via hole with metal. It is found that metal coverage in the bottom of the via hole is reduced to less than 10% due to the high aspect ratio, and an undercut may be formed. Further, it is found that the via suffers from even lower step coverage at the bottom and corners of the via hole, and thus it may be observed that the via has a discontinuous configuration. It should be realized that a resistance of the via having the undercut or the discontinuous configuration is increased, and the reliability of the interconnect structure and performance of the entire integrated circuit are therefore reduced.

This Discussion of the Background section is for background information only. The statements in this Discussion of the Background are not an admission that the subject matter disclosed in this section constitutes a prior art to the present disclosure, and no part of this section may be used as an admission that any part of this application, including this Discussion of the Background section, constitutes prior art to the present disclosure.

### SUMMARY

One aspect of the present disclosure provides an interconnect structure. The interconnect structure includes a first connecting line, a second connecting line disposed over the first connecting line, and a connecting via disposed in a dielectric structure between the first connecting line and the second connecting line. The connecting via electrically connects the first connecting line to the second connecting line. In some embodiments, the connecting via includes a head portion and a body portion. In some embodiments, a width of the head portion is greater than a width of the body portion.

In some embodiments, the width of the head portion of the connecting via is less than a width of the second connecting line.

In some embodiments, a ratio of the width of the head portion to the width of the body portion is less than approximately 3.

In some embodiments, the dielectric structure includes a multilayer structure.

In some embodiments, the dielectric structure includes two first dielectric layers and a second dielectric layer disposed between the two first dielectric layers. In some embodiments, an etching rate of the second dielectric layer is different from an etching rate of the two first dielectric layers.

In some embodiments, a height of the head portion of the connecting via is equal to a height of the body portion of the connecting via. In some embodiments, the height of the head portion of the connecting via is greater than the height of the body portion of the connecting via.

In some embodiments, the head portion and the body portion are monolithic.

One aspect of the present disclosure provides a method for preparing an interconnect structure. The method includes the following steps. A first dielectric structure is provided over a first connecting line. A first via opening is formed in the first dielectric structure. A second via opening is formed over and coupled to the first via opening. A connecting via is formed in the first via opening and the second via opening. A second connecting line is formed over the connecting via.

In some embodiments, the first connecting line is exposed through a bottom of the first via opening.

In some embodiments, the first dielectric structure is exposed through a bottom of the first via opening.

In some embodiments, a depth of the first via opening is equal to half of a thickness of the first dielectric structure. In some embodiments, the depth of the first via opening is less than half of the thickness of the first dielectric structure.

In some embodiments, the forming of the second via opening further includes deepening the first via opening to expose the first connecting line.

In some embodiments, a ratio of a width of the second via opening to a width of the first via opening is less than approximately 3.

In some embodiments, the first dielectric structure includes a multilayer structure.

In some embodiments, the first dielectric structure includes two first dielectric layers and a second dielectric layer disposed between the two first dielectric layers. In some embodiments, an etching rate of the second dielectric layer is different from an etching rate of the two first dielectric layers.

In some embodiments, a depth of the second via opening is equal to or greater than a depth of the first via opening.

In some embodiments, the forming of the connecting via further includes the following steps. The first via opening and the second via opening are filled with a first conductive layer. A planarization is performed to remove a portion of the first conductive layer to expose the first dielectric structure.

In some embodiments, a top surface of the connecting via and a top surface of the first dielectric structure are coplanar.

In some embodiments, the first conductive layer includes a recessed region after the planarization.

In some embodiments, the forming of the second connecting line includes the following steps. A second dielectric structure is formed over the first dielectric structure. In some embodiments, the recessed region is filled with the second dielectric structure. A portion of the second dielectric structure is removed to form a line opening. In some embodiments, the connecting via is exposed through the line opening. The line opening is filled with a second conductive layer.

In the present disclosure, a method for preparing the semiconductor package structure is provided. According to the method, the first and second via openings are sequentially formed. Because the width of the second via opening is greater than the width of the first via opening, the first via opening can be easily filled with the first conductive layer. It is found that a step coverage of the conductive layer at the bottom and corners of the first via opening is improved, and thus resistance of the formed connecting via is reduced. Further, because a width of the head portion of the connecting via is greater than a width of the body portion of the connecting via, an alignment window between the second connecting line and the connecting via is improved, and thus process complexity can be reduced.

In contrast, with a comparative method, the connecting via used to electrically connect the first and second connecting lines suffers from poor coverage at the bottom and corners, and thus resistance of the connecting via is increased. Consequently, an interconnect structure formed by the comparative method suffers from reduced reliability and electrical performance.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

A more complete understanding of the present disclosure may be derived by referring to the detailed description and claims. The disclosure should also be understood to be connected to the figures' reference numbers, which refer to similar elements throughout the description, and:

FIG. 1 is a flow diagram illustrating a method for preparing an interconnect structure in accordance with a first embodiment of the present disclosure.

FIGS. 2 to 6 are schematic diagrams illustrating various fabrication stages of the method for preparing the interconnect structure in accordance with the first embodiment of the present disclosure.

FIGS. 7A and 7B are schematic diagrams illustrating the interconnect structure in accordance with some embodiments of the present disclosure, respectively.

FIG. 8 is a flow diagram illustrating a method for preparing an interconnect structure in accordance with a second embodiment of the present disclosure.

FIGS. 9 to 12 are schematic diagrams illustrating various fabrication stages of the method for preparing the semiconductor package structure in accordance with the second embodiment of the present disclosure.

FIGS. 13 to 16 are schematic diagrams illustrating various fabrication stages of the method for preparing the interconnect structure in accordance with a third embodiment of the present disclosure.

FIGS. 17 to 20 are schematic diagrams illustrating various fabrication stages of the method for preparing the interconnect structure in accordance with a fourth embodiment of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another element, component, region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limiting to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

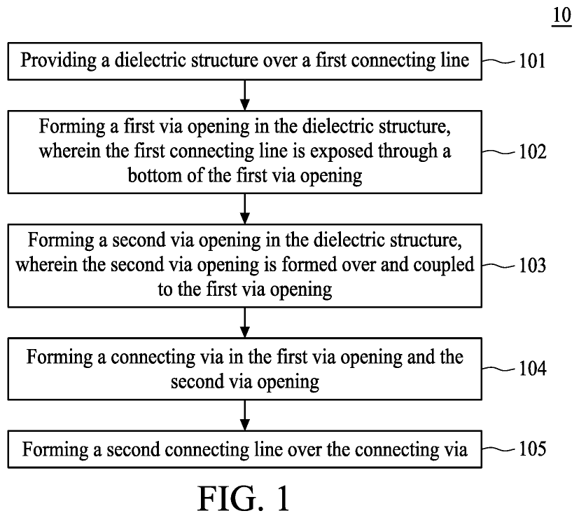

FIG. 1 is a flow diagram illustrating a method for preparing an interconnect structure 10 in accordance with a first embodiment of the present disclosure. The method for preparing a semiconductor structure 10 includes a step 101, providing a dielectric structure over a first connecting line. The method 10 further includes a step 102, forming a first via opening in the dielectric structure. In the first embodiment, the first connecting line is exposed through a bottom of the first via opening. The method 10 further includes a step 103, forming a second via opening in the dielectric structure. In some embodiments, the second via opening is formed over and coupled to the first via opening. The method 10 further includes a step 104, forming a connecting via in the first via opening and the second via opening. The method 10 further includes a step 105, forming a second connecting line over the connecting via. The method for preparing the interconnect structure 10 will be further described according to one or more embodiments below.

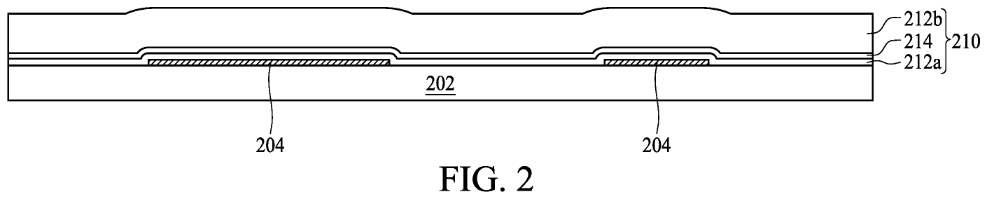

FIGS. 2 to 6 are schematic drawings illustrating various fabrication stages of the method for preparing the interconnect structure 10 in accordance with the first embodiment of the present disclosure. Referring to FIG. 2, a substrate 202 is provided. In some embodiments, the substrate 202 is fabricated with a predetermined functional circuit within the substrate 202 produced by photolithography processes. In some embodiments, the substrate 202 may include various elements (not shown), including transistors, resistors, capacitors, and other semiconductor elements which are well-known in the art.

Referring to FIG. 2, the substrate 202 includes a first connecting line 204 disposed thereon. The first connecting line 204 can be formed by methods known in the art, for example, copper damascene processes. In some embodiments, the first connecting line 204 can be encapsulated by a barrier layer (not shown) and/or a capping layer (not shown). In some embodiments, the barrier layer may include titanium (Ti), tantalum (Ta), titanium nitride (TiN), or tantalum nitride (TaN). In some embodiments, the capping layer may include silicon nitride (SiN), silicon carbide (SiC), silicon oxide (SiO) or the like. In some embodiments, the first connecting line 204 can be a lower metal line in an interconnect structure to be formed. For example, the first connecting line 204 can be at a metal-2 (M2) level of the interconnect structure. In other embodiments, the first connecting line 204 can be at an M3 level of the interconnect structure. In still other embodiments, the first connecting line 204 can be at an Mn level or a top level (Mₜₒₚ) of the interconnect structure, wherein n is a positive integer greater than 1.

Still referring to FIG. 2, a dielectric structure 210 is provided over the first connecting line 204, according to step 101. In some embodiments, a thickness of the dielectric structure 210 is less than approximately 8 μm when the first connecting line 204 is at the M3 level of the interconnect structure, but the disclosure is not limited thereto. It should be understood that the thickness of the dielectric structure 210 can be adjusted according to the level where the first connecting line 204 is disposed. In some embodiments, the dielectric structure 210 includes a single layer. In such embodiments, the dielectric structure 210 can include SiO, phosphosilicate glass (PSG), borophosphosilicate glass (BPSG), low dielectric constant (k) material such as fluorosilicate glass (FSG), organosilicate glass (OSG), or a combination thereof.

In other embodiments, the dielectric structure 210 includes a multilayer structure. For example but not limited thereto, the dielectric structure 210 can include two first dielectric layers 212a, 212b and a second dielectric layer 214 disposed between the two first dielectric layers 212a and 212b. Further, an etching rate of the second dielectric layer 214 is different from an etching rate of the two first dielectric layers 212a and 212b, but the disclosure is not limited thereto. For example, the two first dielectric layers 212a, 212b can include SiN, and the second dielectric layer 214 can include SiO, but the disclosure is not limited thereto. In some embodiments, the two first dielectric layers 212a, 212b can include a thin layer 212a in contact with the first connecting line 204 and a thick layer 212b separated from the thin layer by the second dielectric layer 214, as shown in FIG. 2. In some embodiments, a thickness of the thin first dielectric layer 212a is approximately 1 μm, but the disclosure is not limited thereto. In some embodiments, a thickness of the second dielectric layer 214 is approximately 0.8 μm, but the disclosure is not limited thereto. In some embodiments, a thickness of the thick first dielectric layer 212b is approximately 5.5 μm, but the disclosure is not limited thereto. Those skilled in the art would easily realize that the thicknesses of the two first dielectric layers 212a, 212b and the second dielectric layer 214 can be adjusted depending on different product or process requirements.

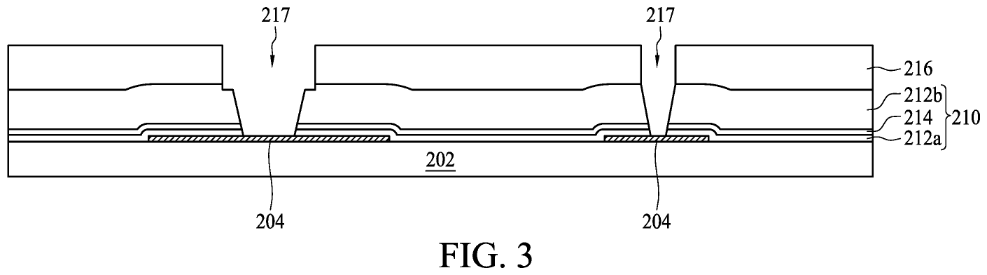

Referring to FIG. 3, a first via opening 217 is formed in the dielectric structure 210, according to step 102. In some embodiments, a patterned mask 216 can be formed over the dielectric structure 210, and an etching process can be performed to etch the dielectric structure 210 through the patterned mask 216. Consequently, the first via opening 217 is formed in the dielectric structure 210. In some embodiments, the etching process can be a dry etching process, but the disclosure is not limited thereto. Consequently, the first via opening 217 is formed. Significantly, the first via opening 217 penetrates the dielectric structure 210, such that a portion of the first connecting line 204 is exposed through a bottom of the first via opening 217, as shown in FIG. 3. After the forming of the first via opening 217, the patterned mask 216 can be removed.

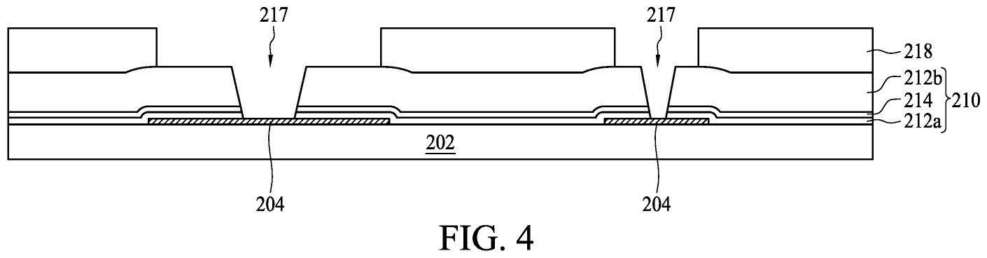

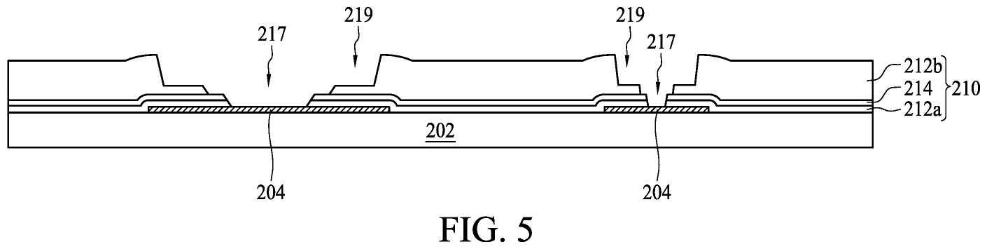

Referring to FIGS. 4 and 5, a second via opening 219 is formed in the dielectric structure 210, according to step 103. In some embodiments, a patterned mask 218 can be formed over the dielectric structure 210. As shown in FIG. 4, the first via opening 217 is exposed through the patterned mask 218. Further, a portion of the dielectric structure 210 and the portion of the first connecting line 204 are also exposed through the patterned mask 218.

Referring to FIG. 5, an etching process can be performed to etch the dielectric structure 210 through the patterned mask 218. Consequently, the second via opening 219 is formed in the dielectric structure 210. In some embodiments, the etching process can be a dry etching process, but the disclosure is not limited thereto. Consequently, the second via opening 219 is formed over and coupled to the first via opening 217. Significantly, the dielectric structure 210 is exposed through sidewalls and a bottom of the second via opening 219, and is also exposed through sidewalls of the first via opening 217, while the first connecting line 204 is exposed through a bottom of the first via opening 217, as shown in FIG. 5. In some embodiments, the thick first dielectric layer 212b is exposed through the sidewalls of the second via opening 219, the bottom of the second via opening 219 and the sidewalls of the first via opening 217, while the second dielectric layer 214 and the thin first dielectric layer 212a are exposed through the sidewalls of the first via opening 217. After the forming of the second via opening 219, the patterned mask 218 can be removed.

In some embodiments, a width of the second via opening 219 is greater than a width of the first via opening 217. In some embodiments, a ratio of the width of the second via opening 219 to the width of the first via opening 217 is less than approximately 3, but the disclosure is not limited thereto. In some embodiments, the ratio is between approximately 2 and approximately 3, but the disclosure is not limited thereto. In still other embodiments, the ratio is between approximately 1.8 and approximately 2, but the disclosure is not limited thereto. In some embodiments, a depth of the second via opening 219 can be equal to or greater than a depth of the first via opening 217, but the disclosure is not limited thereto.

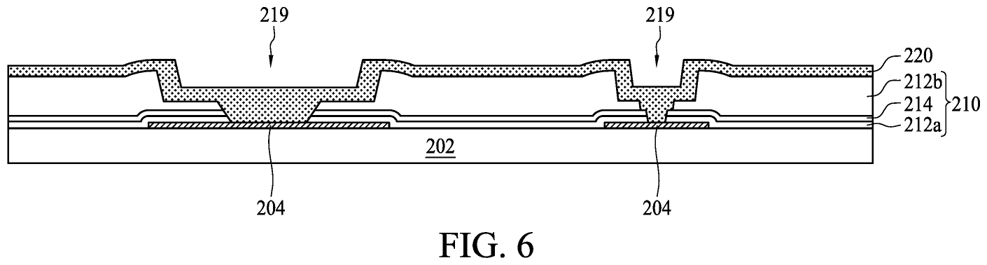

Referring to FIG. 6, a first conductive layer 220 is formed to fill at least the first via opening 217 and a portion of the second via opening 219. In some embodiments, the first conductive layer 220 can be conformally formed along a top surface of the dielectric structure 210 and the sidewalls and bottoms of the first and second via openings 217 and 219. In some embodiments, the first conductive layer 220 can be formed by physical vapor deposition (PVD), but the disclosure is not limited thereto. In some embodiments, a diffusion barrier layer (not shown) including Ti, TiN, Ta, TaN or a combination thereof is formed before the forming of the first conductive layer 220.

Still referring to FIG. 6, because the width of the second via opening 219 is greater than the width of the first via opening 217, the first via opening 217 can be easily filled with the first conductive layer 220. It is found that a step coverage of the conductive layer 220 at bottom and corners of the first via opening 217 is improved, and thus resistance is reduced.

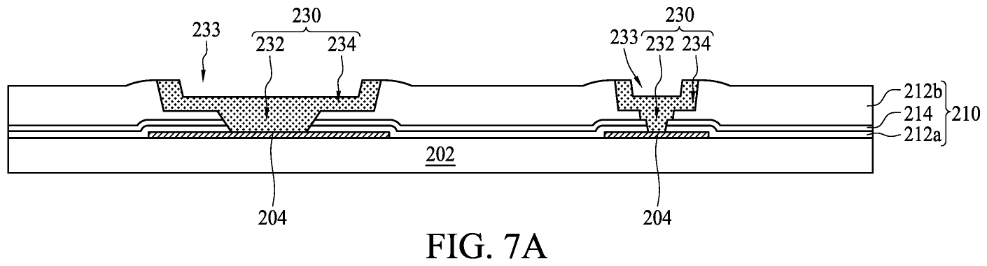

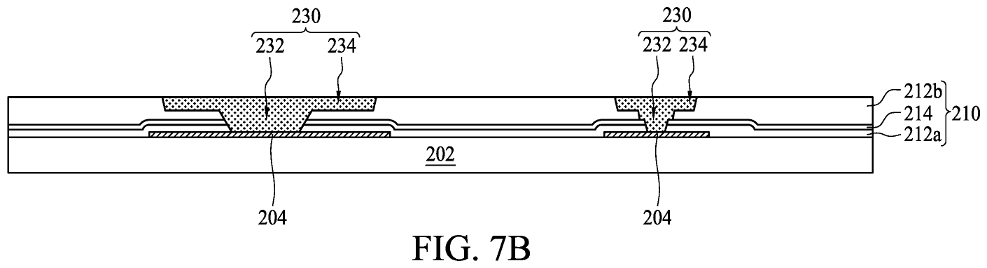

Referring to FIG. 7A, after the forming of the first conductive layer 220, a planarization such as a chemical mechanical polishing (CMP) is performed to remove a portion of the first conductive layer 220 to expose the dielectric structure 210. In some embodiments, the CMP can be stopped once the dielectric structure 210 is exposed, as shown in FIG. 7A. Accordingly, a connecting via 230 is obtained, according to step 104. In some embodiments, the connecting via 230 has a T shaped. In some embodiments, the connecting via 230 includes a body portion 232 and a head portion 234 coupled to each other. In such embodiments, a recess region 233 may be formed in the head portion 234 of the connecting via 230 after the planarization, as shown in FIG. 7A.

Referring to FIG. 7B, in other embodiments, the planarization is performed to remove not only a portion of the first conductive layer 220 but also a portion of the dielectric structure 210. Accordingly, a connecting via 230 is obtained, according to step 104. Further, a thickness of the dielectric structure 210 may be reduced in such embodiments. The connecting via 230 includes a body portion 232 and a head portion 234 coupled to each other. In such embodiments, a top surface of the head portion 234 of the connecting via 230 and a top surface of the dielectric structure 210 are coplanar, as shown in FIG. 7B.

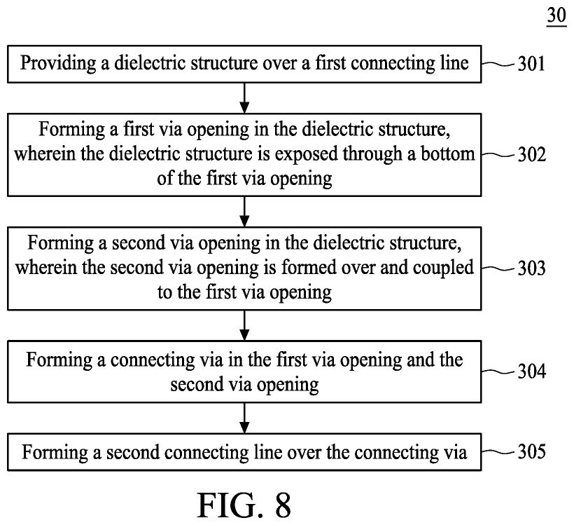

FIG. 8 is a flow diagram illustrating a method for preparing an interconnect structure 30 in accordance with a second embodiment of the present disclosure. The method for preparing a semiconductor structure 30 includes a step 301, providing a dielectric structure over a first connecting line. The method 30 further includes a step 302, forming a first via opening in the dielectric structure. In the second embodiment, the dielectric structure is exposed through a bottom of the first via opening. The method 30 further includes a step 303, forming a second via opening in the dielectric structure. In some embodiments, the second via opening is formed over and coupled to the first via opening. The method 30 further includes a step 304, forming a connecting via in the first via opening and the second via opening. The method 10 further includes a step 305, forming a second connecting line over the connecting via. The method for preparing the interconnect structure 30 will be further described according to one or more embodiments below.

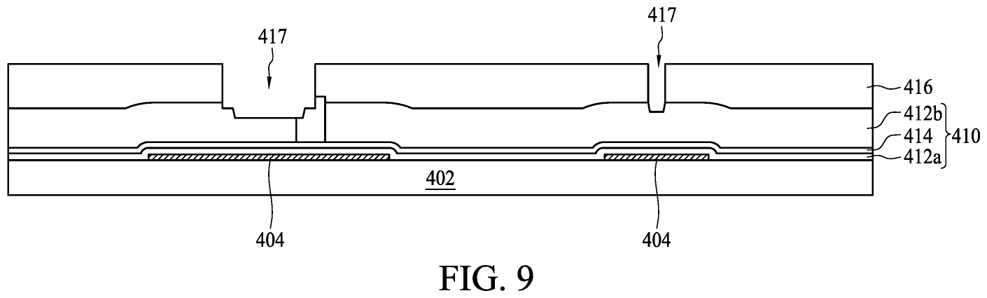

FIGS. 9 to 13 are schematic drawings illustrating various fabrication stages of the method for preparing the interconnect structure in accordance with the second embodiment of the present disclosure. It should be understood that similar features in FIGS. 2 to 6 and 9 to 13 can include similar materials and similar parameters, and thus descriptions of such details are omitted in the interest of brevity.

Referring to FIG. 9, a substrate 402 is provided. As mentioned above, the substrate 402 is fabricated with a predetermined functional circuit within the substrate 402 produced by photolithography processes. In some embodiments, the substrate 402 may include various elements (not shown), including transistors, resistors, capacitors, and other semiconductor elements which are well-known in the art. The substrate 402 includes a first connecting line 404 disposed thereon. In some embodiments, the first connecting line 404 can be encapsulated by a barrier layer (not shown) and/or a capping layer (not shown). As mentioned above, the first connecting line 404 can be a lower metal line in an interconnect structure to be formed. For example the first connecting line 404 can be at an Mn level of the interconnect structure or a top level (Mₜₒₚ) of the interconnect structure, wherein n is a positive integer greater than 1.

Still referring to FIG. 9, a dielectric structure 410 is provided over the first connecting line 404, according to step 301. In some embodiments, the dielectric structure 410 includes a single layer. In other embodiments, the dielectric structure 410 includes a multilayer structure. For example but not limited thereto, the dielectric structure 410 can include two first dielectric layers 412a, 412b and a second dielectric layer 414 disposed between the two first dielectric layers 412a and 412b. Further, an etching rate of the second dielectric layer 414 is different from an etching rate of the two first dielectric layers 412a and 412b, but the disclosure is not limited thereto. In some embodiments, the two first dielectric layers 412a, 412b can include a thin layer 412a in contact with the first connecting line 404 and a thick layer 412b separated from the thin layer by the second dielectric layer 414, as shown in FIG. 9. Those skilled in the art would easily realize that the thicknesses of the two first dielectric layers 412a, 412b and the second dielectric layer 414 can be adjusted depending on different product or process requirements.

Referring to FIG. 9, a first via opening 417 is formed in the dielectric structure 410, according to step 302. In some embodiments, a patterned mask 416 can be formed over the dielectric structure 410, and an etching process can be performed to etch the dielectric structure 410 through the patterned mask 416. Consequently, the first via opening 417 is formed in the dielectric structure 410. In some embodiments, the etching process can be a dry etching process, but the disclosure is not limited thereto. Significantly, a portion of the dielectric structure 410 is exposed through sidewalls and a bottom of the first via opening 417, as shown in FIG. 9. In some embodiments, a depth of the first via opening 417 is equal to or less than half of a thickness of the dielectric structure 410, but the disclosure is not limited thereto. After the forming of the first via opening 417, the patterned mask 416 can be removed.

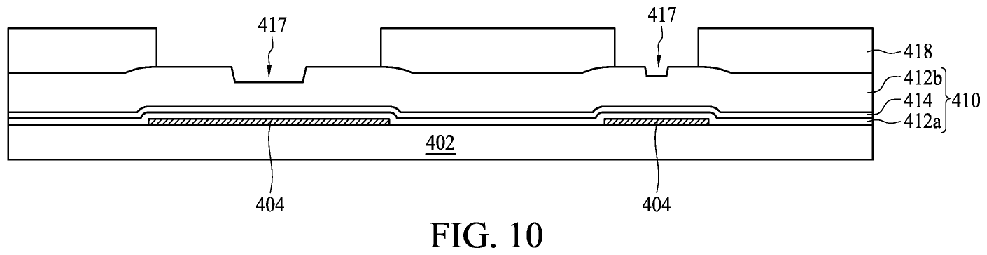

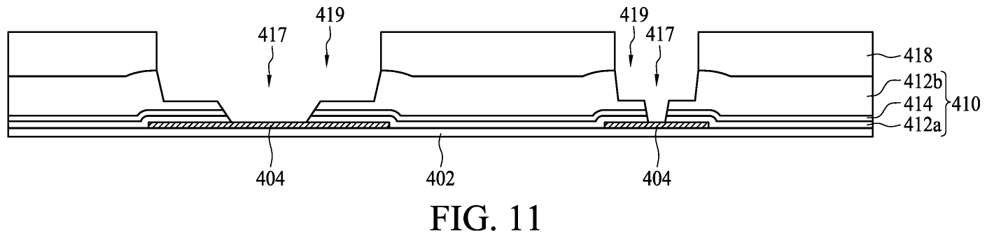

Referring to FIGS. 10 and 11, a second via opening 419 is formed in the dielectric structure 410, according to step 303. In some embodiments, a patterned mask 418 can be formed over the dielectric structure 410. As shown in FIG. 10, the first via opening 417 and a portion of the dielectric structure 410 are exposed through the patterned mask 418.

Referring to FIG. 11, an etching process can be performed to etch the dielectric structure 210 through the patterned mask 418. Consequently, the second via opening 419 is formed in the dielectric structure 210. The etching process can be a dry etching process, but the disclosure is not limited thereto. According to the second embodiment, the first via opening 417 is deepened during the forming of the second via opening 419. In other words, the forming of the second via opening 419 further includes deepening the first via opening 417 and thus the first conductive layer 420 is exposed through a bottom of the first via opening 417 after the forming of the second via opening 419. Consequently, the second via opening 419 is formed over and coupled to the first via opening 417. Significantly, the thick first dielectric layer 412b is exposed through the sidewalls of the second via opening 419, the bottom of the second via opening 419 and the sidewalls of the first via opening 417, while the second dielectric layer 414 and the thin first dielectric layer 412a are exposed through the sidewalls of the first via opening 417.

In some embodiments, a width of the second via opening 419 is greater than a width of the first via opening 417. In some embodiments, a ratio of the width of the second via opening 419 to the width of the first via opening 417 is less than approximately 3, but the disclosure is not limited thereto. In some embodiments, the ratio is between approximately 2 and approximately 3, but the disclosure is not limited thereto. In still other embodiments, the ratio is between approximately 1.8 and approximately 2, but the disclosure is not limited thereto. In some embodiments, a depth of the second via opening 419 can be equal to or greater than a depth of the first via opening 417, but the disclosure is not limited thereto.

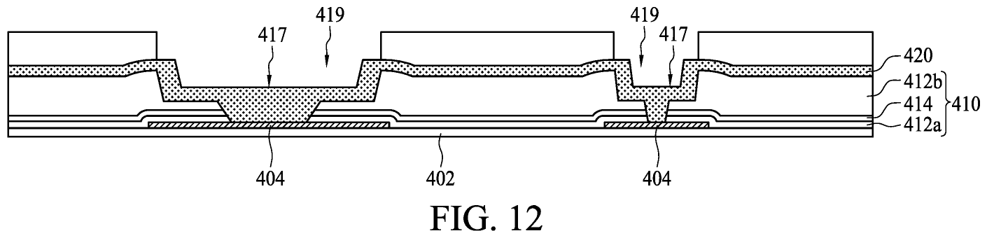

Referring to FIG. 12, a first conductive layer 420 is formed to fill at least the first via opening 417 and a portion of the second via opening 419. In some embodiments, the first conductive layer 420 can be conformally formed along a top surface of the dielectric structure 410 and the sidewalls and bottoms of the first and second via openings 417 and 419. In some embodiments, the first conductive layer 420 can be formed by PVD, but the disclosure is not limited thereto. In some embodiments, a diffusion barrier layer (not shown) including Ti, TiN, Ta, TaN or a combination thereof is formed before the forming of the first conductive layer 420.

Still referring to FIG. 12, because the width of the second via opening 419 is greater than the width of the first via opening 417, the first via opening 417 can be easily filled with the first conductive layer 420. It is found that a step coverage of the first conductive layer 420 at the bottom and corners of the first via opening 417 is improved, and thus resistance is reduced. Further, because the first connecting line 404 is exposed during the forming of the second via opening 419, a consumption issue of the first connecting line 404 can be mitigated.

It should be noted that after the forming of the first conductive layer 420, a planarization, such as a CMP, is performed to remove a portion of the first conductive layer 420 to expose the dielectric structure 410. In some embodiments, the CMP can be stopped once the dielectric structure 410 is exposed. Accordingly, a connecting via 230 as shown in FIG. 7A is obtained, according to step 304. The connecting via 230 includes a body portion 232 and a head portion 234 coupled to each other. In such embodiments, a recess region 233 may be formed in the head portion 234 of the connecting via 230 after the planarization, as shown in FIG. 7A.

Referring to FIG. 7B, in other embodiments, the planarization is performed to remove not only a portion of the first conductive layer 420 but also a portion of the dielectric structure 410. Accordingly, a connecting via 230 is obtained. Further, a thickness of the dielectric structure 210 may be reduced in such embodiments. The connecting via 230 includes a body portion 232 and a head portion 234 coupled to each other. In such embodiments, a top surface of the head portion 234 of the connecting via 230 and a top surface of the dielectric structure 210 are coplanar, as shown in FIG. 7B.

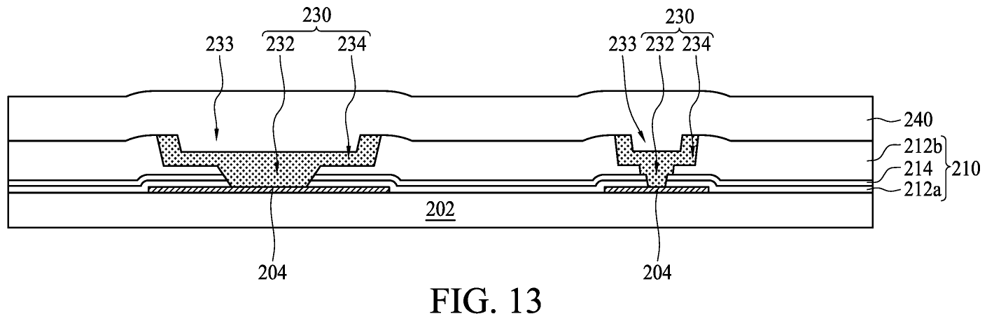

In some embodiments, a second connecting line can be formed after the forming of the connecting via 230, according to step 105 or step 305. FIGS. 13 to 16 are schematic diagrams illustrating various fabrication stages for forming the second connecting line according to the method for preparing the interconnect structure in accordance with a third embodiment of the present disclosure. It should be understood that although the elements in FIGS. 13 to 16 are depicted as those in FIGS. 2 to 7A, the steps can be performed after the forming the connecting via 430 as shown in FIGS. 9 to 12, and therefore descriptions of such details are omitted in the interest of brevity.

Referring to FIG. 13, a dielectric structure 240 is formed over the dielectric structure 210. In some embodiments, the dielectric structure 240 can include a layer including SiO, PSG, BPSG, low-k material such as FSG or OSG or a combination thereof. In other embodiments, the dielectric structure 240 includes a multilayer structure, wherein the multilayer structure can be similar to or different from that of the dielectric structure 210, depending on the product or process requirements. In some embodiments, a thickness of the dielectric structure 240 can be similar to or different from the thickness of the dielectric structure 210, depending on the product or process requirements. Significantly, the recessed region 233 is filled with the dielectric structure 240.

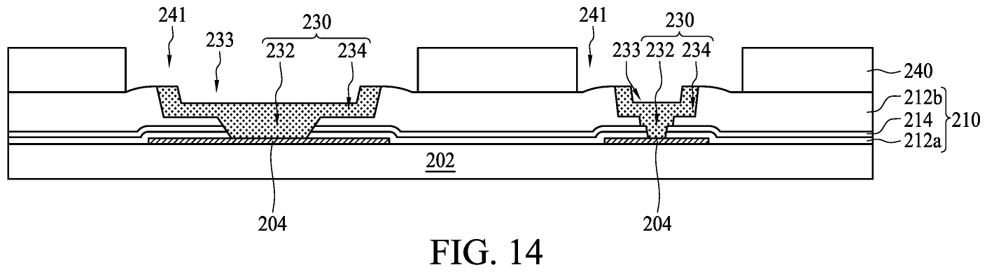

Referring to FIG. 14, a portion of the dielectric structure 240 is removed to form a line opening 241. Significantly, the T-shaped connecting via 230 is entirely exposed through the line opening 241. Further, the dielectric structure 240 previously filling the recessed region 233 over the head portion 234 of the connecting via 230 is now entirely removed.

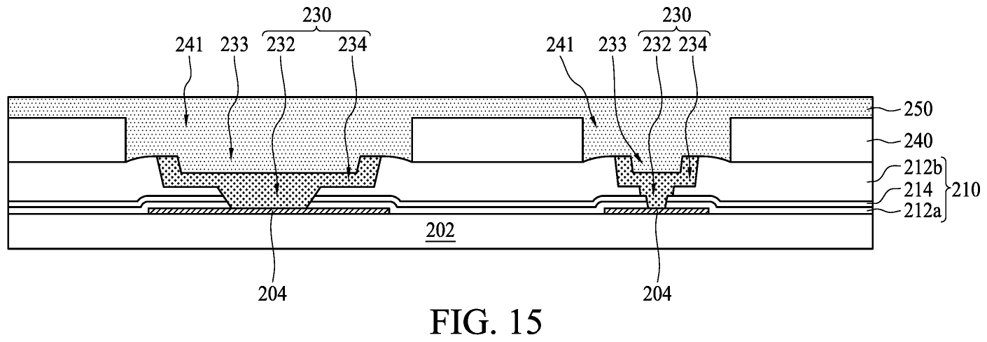

Referring to FIG. 15, a second conductive layer 250 is then formed to fill the line opening 241. In some embodiments, a diffusion barrier layer (not shown) including Ti, TiN, Ta, TaN or a combination thereof can be formed before the forming of the second conductive layer 250.

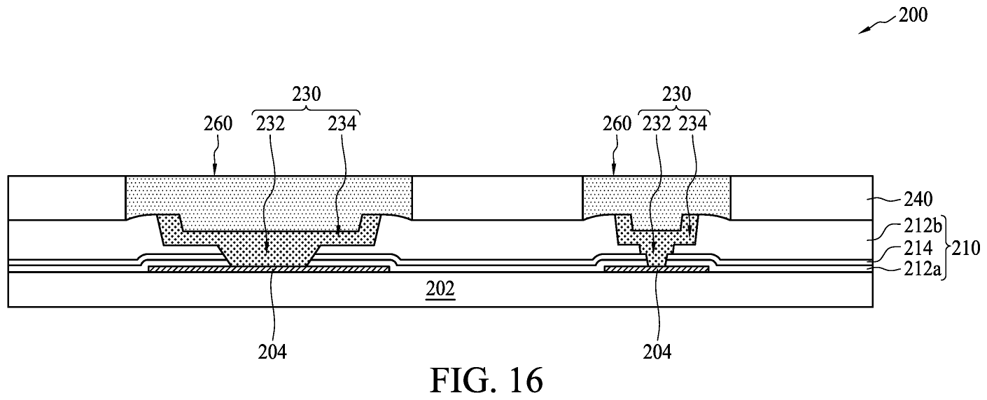

Referring to FIG. 16, after the forming of the second conductive layer 250, a planarization such as a CMP is performed to remove a portion of the second conductive layer 250 to expose the dielectric layer 240. Accordingly, a second connecting line 260 is formed, and a top surface of the second connecting line 260 and a top surface of the dielectric structure 240 are coplanar.

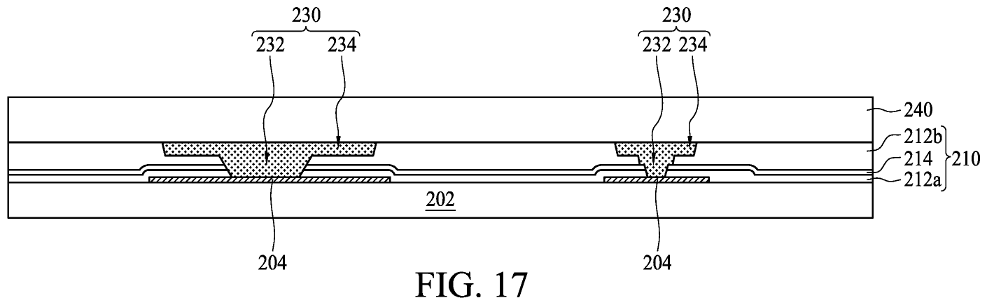

Please refer to FIGS. 17 to 20, which are schematic diagrams illustrating various fabrication stages for forming the second connecting structure according to the method for preparing the interconnect structure in accordance with a fourth embodiment of the present disclosure. It should be understood that although the elements in FIGS. 17 to 20 are depicted as those in FIGS. 2 to 7A, such steps can be performed after the forming of the connecting via 430 as shown in FIGS. 9 to 12, and therefore descriptions of such details are omitted in the interest of brevity.

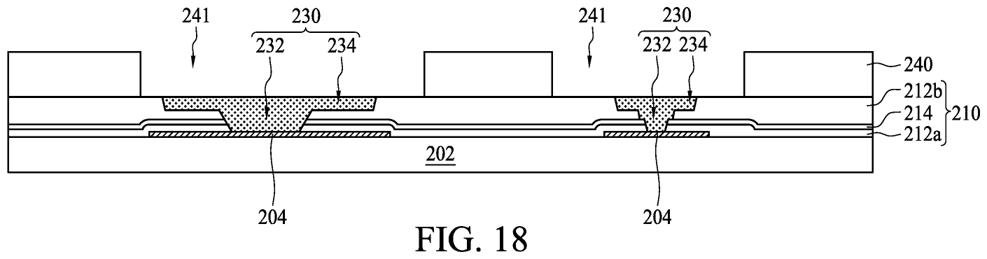

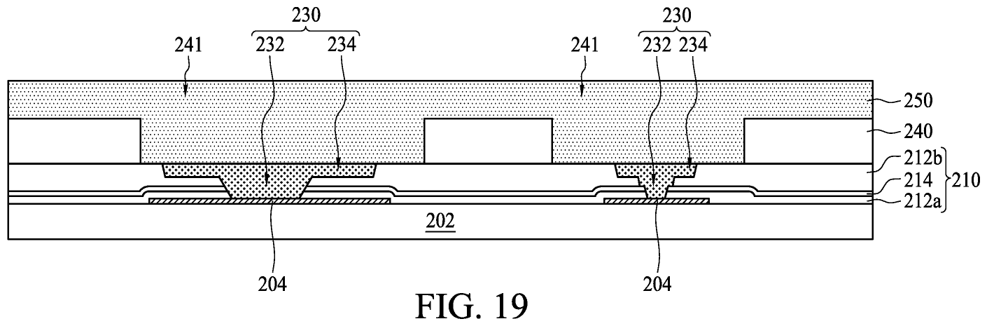

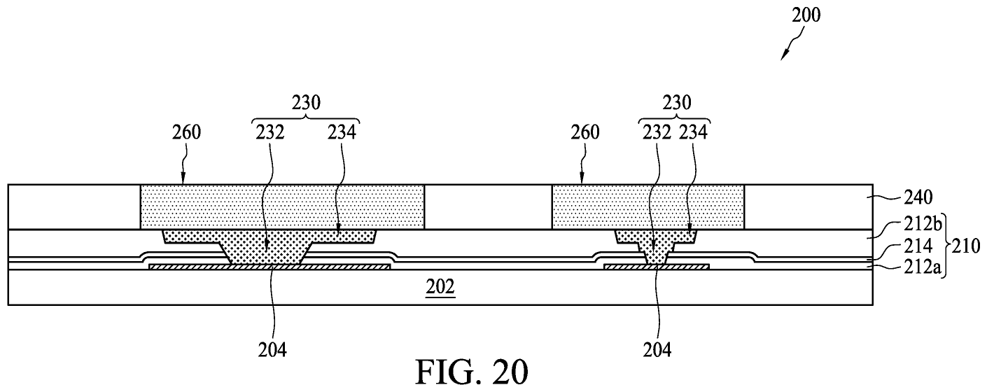

Referring to FIG. 17, a dielectric structure 240 is formed over the dielectric structure 210. Referring to FIG. 18, a portion of the dielectric structure 240 is removed to form a line opening 241. Significantly, the connecting via 230 is entirely exposed through the line opening 241. Referring to FIG. 19, a second conductive layer 250 is then formed to fill the line opening 241. In some embodiments, a diffusion barrier layer (not shown) can be formed before the forming of the second conductive layer 250. Referring to FIG. 20, after the forming of the second conductive layer 250, a planarization is performed to remove a portion of the second conductive layer 250 to expose the dielectric structure 240. Accordingly, a second connecting line 260 is formed, and a top surface of the second connecting line 260 and a top surface of the dielectric structure 240 are coplanar.

As shown in FIGS. 16 and 20, an interconnect structure 200 is obtained according to the methods mentioned above. The interconnect structure 200 includes a first connecting line 204, a second connecting line 260 disposed over the first connecting line 204, and a T-shaped connecting via 230 disposed in the dielectric structure 210 between the first connecting line 204 and the second connecting line 260. Significantly, the first connecting line 204 and the second connecting line 260 are electrically connected to each other by the connecting via 230. In some embodiments, the first connecting line 204 can be at an Mn level of the interconnect structure 200, and the second connecting line can be at an Mn+1 level of the interconnect structure 200. For example, the first connecting line 204 can be at an M3 level of the interconnect structure 200, and the second connecting line can be at an M4 level of the interconnect structure 200, but the disclosure is not limited thereto.

The connecting via 230 includes a head portion 234 and a body portion 232. In some embodiments, a width of the head portion 234 is greater than a width of the body portion 232. Specifically, a ratio of the width of the head portion 234 to the width of the body portion 232 is less than approximately 3. In some embodiments, the ratio of the width of the head portion 234 to the width of the body portion 232 is between approximately 2 and approximately 3. In other embodiments, the ratio of the width of the head portion 234 to the width of the body portion 232 is between approximately 1.8 and approximately 2. Further, the width of the head portion 234 of the connecting via 230 is less than a width of the second connecting line 260. In some embodiments, a height of the head portion 234 of the connecting via 230 is equal to a height of the body portion 232 of the connecting via 230. In other embodiments, the height of the head portion 234 of the connecting via 230 is greater than the height of the body portion 232 of the connecting via 230, depending on the process requirement. Because the head portion 234 and the body portion 232 are simultaneously formed by filling the first and second via openings 217, 219 or 417, 419, the head portion 234 and the body portion 232 are monolithic.

In the present disclosure, a method for preparing the semiconductor package structure 10 or 30 is provided. According to the methods 10 and 30, the first and second via openings 217, 219 or 417, 419 are sequentially formed. Because the width of the second via opening 219 or 419 is greater than the width of the first via opening 217 or 417, the first via opening 217 or 417 can be easily filled with the first conductive layer 220 or 420. It is found that a step coverage of the conductive layer 220 or 420 at the bottom and corners of the first via opening 217 or 417 is improved, and thus resistance of the formed connecting via 230 or 430 is reduced. Further, because the width of the head portion 234 of the connecting vias 230 and 430 is greater than the width of the body portion 232, an alignment window between the second connecting line 260 and the connecting via 230 is improved, and thus process complexity can be reduced.

Further, by further removing the portion of the dielectric structure 210 as shown in FIG. 7B, a distance between the first connecting line 204 and the second connecting line 260 can be adjusted. In some embodiments, the capacitance between the first and second connecting lines 204 and 260 can be adjusted accordingly.

In contrast, with a comparative method, the connecting via used to electrically connect the first and second connecting lines suffers from poor coverage at the bottom and corners, and thus resistance of the connecting via is increased. Consequently, an interconnect structure formed by the comparative method suffers from reduced reliability and electrical performance.

One aspect of the present disclosure provides an interconnect structure. The interconnect structure includes a first connecting line, a second connecting line disposed over the first connecting line, and a connecting via disposed in a dielectric structure between the first connecting line and the second connecting line. The connecting via electrically connects the first connecting line to the second connecting line. In some embodiments, the connecting via includes a head portion and a body portion. In some embodiments, a width of the head portion is greater than a width of the body portion.

One aspect of the present disclosure provides a method for preparing an interconnect structure. The method includes the following steps. A first dielectric structure is provided over a first connecting line. A first via opening is formed in the first dielectric structure. A second via opening is formed over and coupled to the first via opening. A connecting via is formed in the first via opening and the second via opening. A second connecting line is formed over the connecting via.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. An interconnect structure, comprising:
a first connecting line;
a second connecting line disposed over the first connecting line; and
a connecting via disposed in a dielectric structure between the first connecting line and the second connecting line, and electrically connecting the first connecting line to the second connecting line; wherein the connecting via comprises a head portion and a body portion, and a width of the head portion is greater than a width of the body portion.

2. The interconnect structure of claim 1, wherein the width of the head portion of the connecting via is less than a width of the second connecting line.

3. The interconnect structure of claim 1, wherein a ratio of the width of the head portion to the width of the body portion is less than approximately 3.

4. The interconnect structure of claim 1, wherein the dielectric structure comprises a multilayer structure.

5. The interconnect structure of claim 4, wherein the dielectric structure comprises two first dielectric layers and a second dielectric layer disposed between the two first dielectric layers, and an etching rate of the second dielectric layer is different from an etching rate of the two first dielectric layers.

6. The interconnect structure of claim 1, wherein a height of the head portion of the connecting via is equal to or greater than a height of the body portion of the connecting via.

7. The interconnect structure of claim 1, wherein the head portion and the body portion are monolithic.

8. A method for preparing an interconnect structure, comprising:
providing a first dielectric structure over a first connecting line;
forming a first via opening in the first dielectric structure;
forming a second via opening in the dielectric structure, wherein the second via opening is formed over and coupled to the first via opening;
forming a connecting via in the first via opening and the second via opening; and
forming a second connecting line over the connecting via.

9. The method of claim 8, wherein the first connecting line is exposed through a bottom of the first via opening.

10. The method of claim 8, wherein the first dielectric structure is exposed through a bottom of the first via opening.

11. The method of claim 10, wherein a depth of the first via opening is equal to or less than half of a thickness of the first dielectric structure.

12. The method of claim 11, wherein the forming of the second via opening further comprises deepening the first via opening to expose the first connecting line.

13. The method of claim 8, wherein a ratio of a width of the second via opening to a width of the first via opening is less than approximately 3.

14. The method of claim 8, wherein the first dielectric structure comprises a multilayer structure.

15. The method of claim 14, wherein the first dielectric structure comprises two first dielectric layers and a second dielectric layer disposed between the two first dielectric layers, and an etching rate of the second dielectric layer is different from an etching rate of the two first dielectric layers.

16. The method of claim 8, wherein a depth of the second via opening is equal to or greater than a depth of the first via opening.

17. The method of claim 8, wherein the forming of the connecting via further comprises:
filling the first via opening and the second via opening with a first conductive layer; and
performing a planarization to remove a portion of the first conductive layer to expose the first dielectric structure.

18. The method of claim 17, wherein a top surface of the connecting via and a top surface of the first dielectric structure are coplanar.

19. The method of claim 17, wherein the first conductive layer comprises a recessed region after the planarization.

20. The method of claim 19, wherein the forming of the second connecting line comprises:
forming a second dielectric structure over the first dielectric structure, wherein the recessed region is filled with the second dielectric structure;
removing a portion of the second dielectric structure to form a line opening, wherein the connecting via is exposed through the line opening; and
filling the line opening with a second conductive layer.
